(19) United States
(12) Patent Application Publication
(10) Pub. No.: US 2012/0154656 A1
(43) Pub. Date: Jun. 21, 2012

(54) SOLID-STATE IMAGING ELEMENT, DRIVING METHOD, AND ELECTRONIC APPARATUS

(75) Inventors: Yusuke OIKE, Kanagawa (JP); Takafumi TAKATSUKA, Kanagawa (JP); Ikuhiro YAMAMURA, Kanagawa (JP)

(73) Assignee: SONY CORPORATION, Tokyo (JP)

(21) Appl. No.: 13/312,366

(22) Filed: Dec. 6, 2011

(30) Foreign Application Priority Data
Dec. 15, 2010 (JP) 2010-279509

(51) Int. Cl. H04N 5/335

(52) U.S. Cl. 348/308; 348/E05.091

(57) ABSTRACT

A solid-state imaging element is disclosed which includes: a pixel array portion configured to have a plurality of unit pixels arrayed two-dimensionally, the unit pixels being furnished with a photoelectric conversion portion, a transfer section, and a reset section, the transfer section being configured to transfer electrical charges accumulated in the photoelectric conversion portion to a charge retention portion, the reset section being configured to reset the electrical charges of the charge retention portion; and a drive control section configured to control the driving of the unit pixels; wherein the drive control section controls the driving of the unit pixels in such a manner that prior to the charge transfer by the transfer section, the reset section resets the electrical charges of the charge retention portion in increments of a plurality of rows of the unit pixels, the plurality of rows being not adjacent to one another.

### BACKGROUND

The present disclosure relates to a solid-state imaging element, a driving method, and an electronic apparatus. More particularly, the disclosure relates to a solid-state imaging element, a driving method, and an electronic apparatus for enhancing the quality of images taken.

Generally, the typical image sensor (solid-state imaging element) is arranged to place electrical charges accumulated in its light-receiving portion into a charge-to-voltage conversion portion (so-called floating diffusion region; referred to as the FD region hereunder where appropriate) or into a charge retention portion such as a capacitance element furnished for each pixel apart from the FD portion for purpose of temporary charge retention. The major purpose of this arrangement is to minimize discrepancies between the pixels in sequential signal read operations over the period of exposure and charge retention (e.g., see Japanese Patent Laid-Open Nos. 2009-268083 and 2005-328493).

Also, when reading signals, the typical image sensor first reads the voltage corresponding to the charges accumulated in the charge retention portion (called the signal level) and then reads the voltage in effect when the charges accumulated in the charge retention portion is reset (called the reset level). Based on the difference between the two levels, the image sensor removes noise.

In the case above, it is preferred that the voltage in effect when the charges in the charge retention portion are reset (initialized) before the charges accumulated in the light-receiving portion are transferred to the charge retention portion (the voltage is called the pre-transfer reset voltage hereunder) should coincide with the reset level in effect when the signal is read out (called the post-read reset voltage hereunder).

### SUMMARY

Meanwhile, when the image sensor has a global shutter operation performed therein to maintain synchronism during a signal charge retention period (see FIG. 1), discharging before the start of exposure (indicated by triangles in FIG. 1) and charge transfer upon completion of exposure (indicated by rectangles) are carried out simultaneously on all pixels. On the other hand, reading of the signal level as well as reading of the reset level is conducted in increments of a pixel row.

Where initialization of the charge retention portion prior to charge transfer is performed simultaneously on all pixels (as indicated by circles), there can be a distinct discrepancy between the pre-transfer reset voltage and the post-read reset voltage because of a voltage drop in the power for reset transistors designed to initialize (i.e., reset) the charge retention portion and due to cross talk between a reset signal line for feeding the reset voltage to the pixels of each adjacent row and the charge retention portion. Also, the load stemming from driving all pixels simultaneously can make the transition timing of the reset operation in this case different from that of the reset operation at signal read time. This can result in a significant difference between the pre-transfer reset voltage and the post-read reset voltage. The marked discrepancy between the pre-transfer reset voltage and the post-read reset voltage produces noise attributable to an offset generated in output (called offset noise hereunder), thus degrading the quality of images taken.

If the charge retention portion prior to charge transfer is initialized serially in increments of a pixel row as indicated (by circles) in FIG. 2, the offset noise may be reduced but it takes a long time to initialize the charge retention portion for all pixel rows. This can lower frame rate, which in turn degrades the quality of images taken (particularly that of moving images).

The present disclosure has been made in view of the above circumstances and provides a solid-state imaging element, a driving method, and an electronic apparatus for enhancing the quality of images taken.

According to one embodiment of the present disclosure, there is provided a solid-state imaging element including: a pixel array portion configured to have a plurality of unit pixels arrayed two-dimensionally, the unit pixels being furnished with a photoelectric conversion portion, a transfer section, and a reset section, the transfer section being configured to transfer electrical charges accumulated in the photoelectric conversion portion to a charge retention portion, the reset section being configured to reset the electrical charges of the charge retention portion; and a drive control section configured to control the driving of the unit pixels. In the solid-state imaging element, the drive control section controls the driving of the unit pixels in such a manner that prior to the charge transfer by the transfer section, the reset section resets the electrical charges of the charge retention portion in increments of a plurality of rows of the unit pixels, the plurality of rows being not adjacent to one another.

Preferably, the drive control section may control the driving of the unit pixels in such a manner that the transfer section performs the charge transfer simultaneously on all unit pixels in the pixel array portion.

Preferably, the drive control section may control the driving of the unit pixels in such a manner that the photoelectric conversion portion is discharged simultaneously for all unit pixels in the pixel array portion.

Preferably, the drive control section may control the driving of the unit pixels in such a manner that the photoelectric conversion portion is discharged and the charge transfer is performed by the transfer section in increments of a plurality of rows of the unit pixels in the pixel array portion, the plurality of rows being adjacent to one another.

Preferably, the reset section may discharge the electrical charges accumulated in the photoelectric conversion portion; and the drive control section may control the driving of the unit pixels in such a manner that after the discharging of the photoelectric conversion portion by the reset section and prior to the charge transfer by the transfer section, the reset section resets the electrical charges of the charge retention portion in increments of a plurality of rows of the unit pixels in the pixel array portion, the plurality of rows being not adjacent to one another.

Preferably, the solid-state imaging element of the present disclosure may further include a discharge section configured to discharge the electrical charges accumulated in the photoelectric conversion portion.

Preferably, the drive control section may control the driving of the unit pixels in such a manner that prior to the discharging of the photoelectric conversion portion by the discharge section, the reset section resets the electrical charges of the charge retention portion in increments of a plurality of rows of the unit pixels in the pixel array portion, the plurality of rows being not adjacent to one another.

Preferably, the drive control section may control the driving of the unit pixels in such a manner that the reset section resets the electrical charges of the charge retention portion in increments of n rows at intervals of m rows of the unit pixels in the pixel array portion.

Preferably, the number m may be 1.

Preferably, the charge retention portion may be a floating diffusion region.

Preferably, the charge retention portion may be a capacitance element furnished apart from the floating diffusion region.

Preferably, the solid-state imaging element of the present disclosure may further include a read section configured to read a voltage reflecting the electrical charges of the charge retention portion. In the solid-state imaging element, the drive control section may control the driving of the unit pixels in such a manner that the reading by the read section of the voltage as a signal level reflecting the electrical charges accumulated in the charge retention portion after the charge transfer, the resetting by the reset section of the electrical charges accumulated in the charge retention portion after the charge transfer, and the reading by the read section of the voltage as a reset level reflecting the electrical charges of the charge retention portion after the charge reset are carried out serially in increments of a row of the unit pixels.

Preferably, the solid-state imaging element of the present disclosure may further include a calculation section configured to calculate a difference between the signal level and the reset level read out by the read section.

According to another embodiment of the present disclosure, there is provided a driving method for use with a solid-state imaging element including a pixel array portion configured to have a plurality of unit pixels arrayed two-dimensionally, the unit pixels being furnished with a photoelectric conversion portion, a transfer section, and a reset section, the transfer section being configured to transfer electrical charges accumulated in the photoelectric conversion portion to a charge retention portion, the reset section being configured to reset the electrical charges of the charge retention portion; and a drive control section configured to control the driving of the unit pixels. The driving method includes: causing the drive control section to control the driving of the unit pixels in such a manner that prior to the charge transfer by the transfer section, the reset section resets the electrical charges of the charge retention portion in increments of a plurality of rows of the unit pixels, the plurality of rows being not adjacent to one another.

According to a further embodiment of the present disclosure, there is provided an electronic apparatus including: a solid-state imaging element including a pixel array portion configured to have a plurality of unit pixels arrayed two-dimensionally, the unit pixels being furnished with a photoelectric conversion portion, a transfer section, and a reset section, the transfer section being configured to transfer electrical charges accumulated in the photoelectric conversion portion to a charge retention portion, the reset section being configured to reset the electrical charges of the charge retention portion; and a drive control section configured to control the driving of the unit pixels; wherein the drive control section controls the driving of the unit pixels in such a manner that prior to the charge transfer by the transfer section, the reset section resets the electrical charges of the charge retention portion in increments of a plurality of rows of the unit pixels, the plurality of rows being not adjacent to one another.

According to the embodiments of the present disclosure, the driving of the unit pixels is controlled in such a manner that prior to the charge transfer by the transfer section, the reset section resets the electrical charges of the charge retention portion in increments of a plurality of rows of the unit pixels, the rows being not adjacent to one another.

Thus according to the embodiments of the present disclosure, it is possible to enhance the quality of images taken.

### BRIEF DESCRIPTION OF THE DRAWINGS

FIG. 1 is an explanatory view showing how an ordinary solid-state imaging element operates;

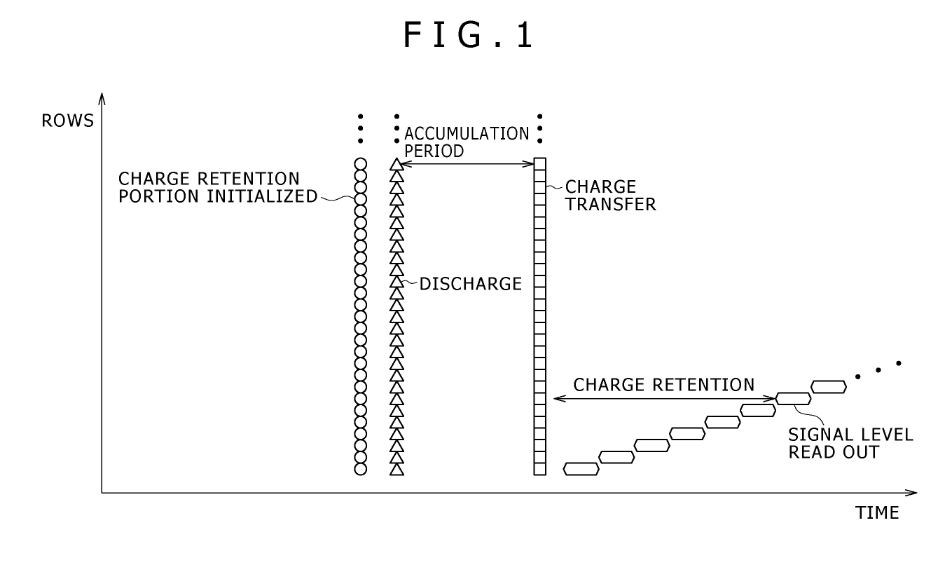

FIG. 2 is another explanatory view showing how the ordinary solid-state imaging element operates;

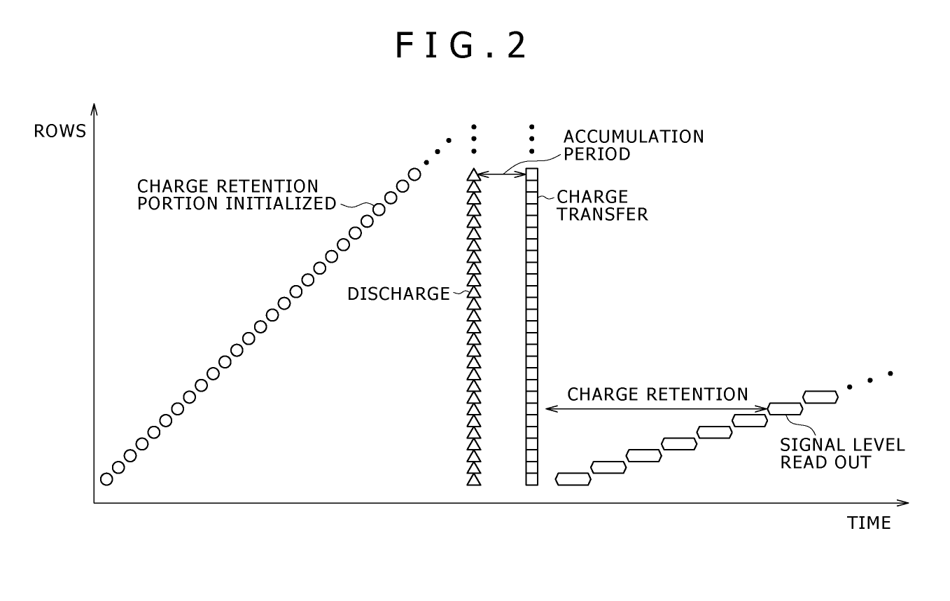

FIG. 3 is a block diagram showing a typical structure of a solid-state imaging element embodying the present disclosure;

FIG. 4 is a schematic view showing a typical structure of a unit pixel;

FIG. 5 is a timing chart showing how a unit pixel is typically driven;

FIG. 6 is an explanatory view showing how the solid-state imaging element is typically driven;

FIG. 7 is another explanatory view showing how the solid-state imaging element is typically driven;

FIG. 8 is a schematic view showing another typical structure of the unit pixel;

FIG. 9 is a schematic view showing another typical structure of the unit pixel;

FIG. 10 is a schematic view showing another typical structure of the unit pixel;

FIG. 11 is a schematic view showing another typical structure of the unit pixel;

FIG. 12 is another timing chart showing how the unit pixel is typically driven;

FIG. 13 is another explanatory view showing how the solid-state imaging element is typically driven;

FIG. 14 is another explanatory view showing how the solid-state imaging element is typically driven;

FIG. 15 is another explanatory view showing how the solid-state imaging element is typically driven;

FIG. 16 is a schematic view showing another typical structure of the unit pixel;

FIG. 17 is a schematic view showing another typical structure of the unit pixel;

FIG. 18 is a schematic view showing another typical structure of the unit pixel; and

FIG. 19 is a block diagram showing a typical structure of an electronic apparatus embodying the

### DETAILED DESCRIPTION OF THE PREFERRED EMBODIMENTS

Some preferred embodiments of the present disclosure will now be described below in reference to the accompanying drawings.

### STRUCTURE OF THE SOLID-STATE IMAGING ELEMENT

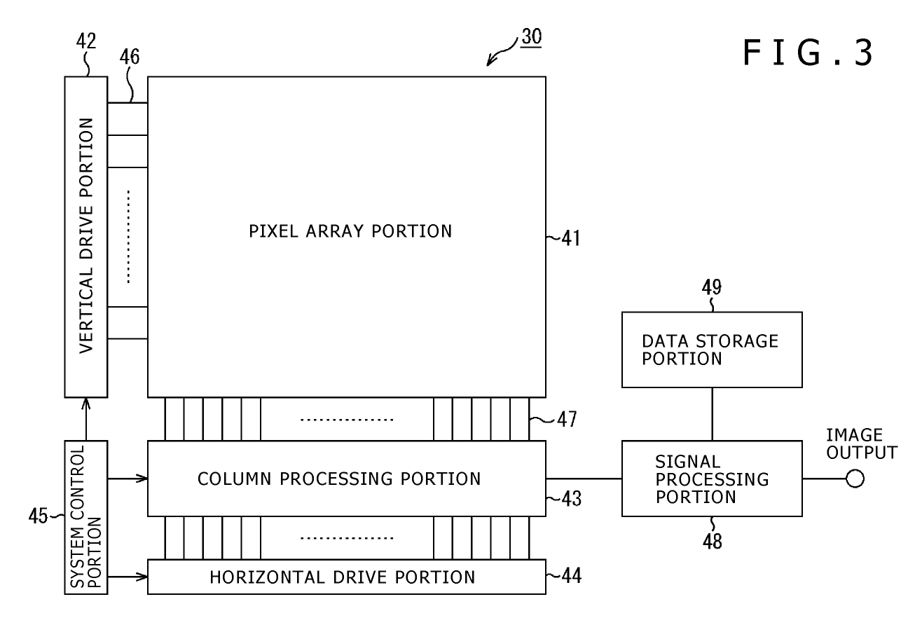

FIG. 3 is a block diagram showing a typical structure of a CMOS (Complementary Metal Oxide Semiconductor) image sensor 30 as a solid-state imaging element embodying the present disclosure.

The CMOS image sensor 30 is structured to include a pixel array portion 41, a vertical drive portion 42, a column processing portion 43, a horizontal drive portion 44, and a system control portion 45. The pixel array portion 41, vertical drive portion 42, column processing portion 43, horizontal drive portion 44, and system control portion 45 are formed on a semiconductor substrate (chip), not shown.

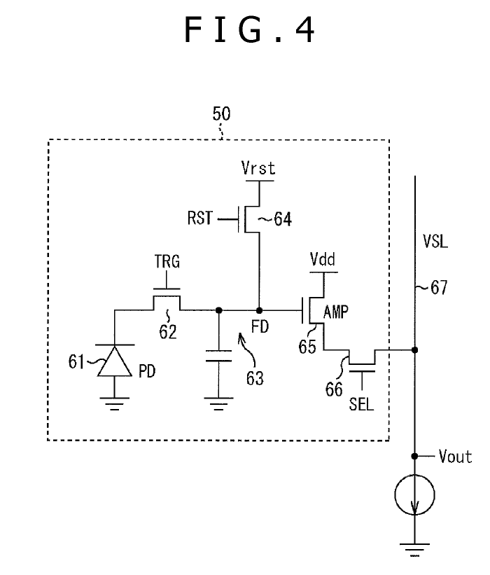

The pixel array portion 41 has unit pixels (one is indicated by reference numeral 50 in FIG. 4) arrayed two-dimensionally in matrix fashion, each of the unit pixels being furnished with a photoelectric conversion element that generates an amount of photocharges reflecting the amount of incident light and stores the generated photocharges inside. In the ensuing description, the amount of photocharges reflecting the amount of incident light may be referred to simply as the charges and the unit pixels simply as the pixels hereunder where appropriate.

Also, the pixel array portion 41 has a pixel drive line 46 formed horizontally per row of pixels (in the direction in which the pixel rows are arrayed) and has a vertical signal line 47 formed vertically per column of pixels (in the direction in which the pixel columns are arrayed). One end of the pixel drive line 46 is connected to the output end of each row in the vertical drive portion 42.

The CMOS image sensor 30 further includes a signal processing portion 48 and a data storage portion 49. The signal processing portion 48 and data storage portion 49 may be provided either in the form of an external signal processing portion such as a DSP (digital signal processor) or of software mounted on a substrate apart from the CMOS image sensor 30, or on the same substrate as the CMOS image sensor 30.

The vertical drive portion 42 may be structured with shift registers and address decoders. As such, the vertical drive portion 42 acts as a pixel drive portion that drives the pixels in the pixel array portion 41 all at once or in increments of rows. The vertical drive portion 42, of which the specific structure is not shown, includes a read scan system, a sweep-out scan system (or simultaneous sweep-out system), and a simultaneous transfer system.

The read scan system scans the unit pixels in the pixel array portion 41 serially and selectively in increments of a row so as to read signals from the unit pixels. In the case of a row drive (rolling shutter operation), a sweep-out scan is performed on each row earlier by the shutter speed time than a read scan to be carried out by the read scan system on the row in question. In the case of a global exposure (global shutter operation), a simultaneous sweep is performed earlier by the shutter speed time than a simultaneous transfer.

The sweep-out discharges (i.e., resets) the unnecessary charges from the photoelectric conversion element of each unit pixel in the row being read. Sweeping out (i.e., resetting) the unnecessary charges causes the so-called electronic shutter operation to be carried out. The electronic shutter operation is an operation that discards the photocharges of the photoelectric conversion element and starts a new exposure (i.e., starts accumulation of photocharges).

The signal read out in a read operation by the read scan system reflects the amount of incident light admitted after the most recent read or electronic shutter operation. In the case of a row drive, the period from the time a unit pixel was read in the most recent read operation or electronic shutter operation for a sweep-out until the time the unit pixel is read by the current read operation provides a photocharge accumulation time (i.e., exposure time) for the unit pixel in question. In the case of a global exposure, the period from a simultaneous sweep to a simultaneous transfer constitutes the charge accumulation time (exposure time).

A pixel signal output from each unit pixel in the pixel row selectively scanned by the horizontal drive portion 42 is fed to the column processing portion 43 via the vertical signal lines 47. For each pixel column in the pixel array portion 41, the column processing portion 43 performs predetermined signal processing on the pixel signals output from the unit pixels of the selected pixel row via the vertical signal lines 47. Also, the column processing portion 43 temporarily retains the pixel signals having undergone the signal processing.

More specifically, the column processing portion 43 performs at least noise removal (e.g., correlated double sampling, or CDS) as part of its signal processing. The correlated double sampling by the column processing portion 43 removes reset noise and fixed pattern noise unique to pixels such as threshold variations in amplification transistors. In addition to the noise removal function, the column processing portion 43 may be equipped with an analog-to-digital (AD) conversion function for outputting signal levels in the form of digital signals.

The horizontal drive portion 44 may be structured with shift registers and address decoders. As such, the horizontal drive portion 44 serially selects unit circuits corresponding to the pixel columns in the column processing portion 43. A selective scan by the horizontal drive portion 44 causes the pixel signals having undergone the signal processing by the column processing portion 43 to be output serially to the signal processing portion 48.

The system control portion 45 is structured with timing generators for generating various timing signals, as well as other elements. Based on the diverse timing signals generated by the timing generators, the system control portion 45 provides drive control on the vertical drive portion 42, column processing portion 43, and horizontal drive portion 44, among others.

The signal processing portion 48 is equipped at least with an addition function that performs diverse signal processing including additions on the pixel signals output from the column processing portion 43. During signal processing by the signal processing portion 48, the data storage portion 49 temporarily stores the data necessary for the processing.

### TYPICAL CIRCUIT STRUCTURE OF THE UNIT PIXEL

Explained below is a typical circuit structure of one of the unit pixels 50 arrayed in matrix fashion in the pixel array portion 41 shown in FIG. 3.

The unit pixel 50 shown in FIG. 4 is made up of a photodiode (PD) 61, a transfer gate 62, a floating diffusion (FD) region 63, a reset transistor 64, an amplification transistor 65, a selection transistor 66, and a vertical signal line 67.

The anode of the photodiode 61 is grounded and its cathode is connected to the source of the transfer gate 62. The drain of the transfer gate 62 is connected to the drain of the reset transistor 64 and to the gate of the amplification transistor 65. The connection point between the drain of the reset transistor 64 and the gate of the amplification transistor 65 constitutes the floating diffusion region 63.

The source of the reset transistor 64 is connected to a predetermined power source Vrst. The source of the amplification transistor 65 is connected to another predetermined power source Vdd. The drain of the amplification transistor 65 is connected to the source of the selection transistor 66. The drain of the selection transistor 66 is connected to the vertical signal line (VSL) 67. The vertical signal line 67 is connected to a constant current source of a source follower circuit.

The gate of the transfer gate 62, the gate of the reset transistor 64, and the gate of the selection transistor 66 are connected to the vertical drive portion 42 shown in FIG. 3 via control lines, not shown. These gates are supplied with pulses acting as drive signals.

The photodiode 61 submits incident light to photoelectric conversion in order to generate an amount of charges reflecting the quantity of incident light and store the generated amount of charges.

In accordance with a drive signal TRG fed from the vertical drive portion 42, the transfer gate 62 turns on or off the transfer of electrical charges from the photodiode 61 to the floating diffusion region 63. For example, when supplied with a High-level (H) drive signal TRG, the transfer gate 62 transfers the charges accumulated in the photodiode 61 to the floating diffusion region 63; when fed with a Low-level (L) drive signal TRG, the transfer gate 62 stops transferring the charges. The photodiode 61 accumulates the charges resulting from the photoelectric conversion performed thereby while the transfer gate 62 is not transferring the charges to the floating diffusion region 63.

The floating diffusion region 63 accumulates the charges transferred from the photodiode 61 via the transfer gate 62 and converts the accumulated charges to a voltage. In the case of a global shutter operation carried out by the CMOS image sensor 30, the floating diffusion region 63 functions as the charge retention portion that retains the charges accumulated in the photodiode 61 during the exposure period.

In accordance with a drive signal RST fed from the vertical drive portion 42, the reset transistor 64 turns or off the discharge of the electrical charges accumulated in the floating diffusion region 63. For example, when supplied with a High-level drive signal RST, the reset transistor 64 clamps the floating diffusion region 63 to the source voltage Vrst in order to discharge (i.e., reset) the charges accumulated in the floating diffusion region 63. When fed with a Low-level drive signal RST, the reset transistor 64 places the floating diffusion region 63 into an electrically floating state.

The amplification transistor 65 amplifies the voltage reflecting the electrical charges accumulated in the floating diffusion region 63. The voltage (voltage signal) amplified by the amplification transistor 65 is output onto the vertical signal line 67 via the selection transistor 66.

In accordance with a drive signal SEL fed from the vertical drive portion 42, the selection transistor 66 turns on or off the output of the voltage signal coming from the amplification transistor 65 onto the vertical signal line 67. For example, when supplied with a High-level drive signal SEL, the selection transistor 66 outputs the voltage signal onto the vertical signal line 67. When fed with a Low-level drive signal SEL, the selection transistor 66 stops outputting the voltage signal.

As explained above, the unit pixel 50 is driven in accordance with the drive signals TRG, RST and SEL fed from the vertical drive portion 42.

### EXAMPLE OF DRIVING THE UNIT PIXEL

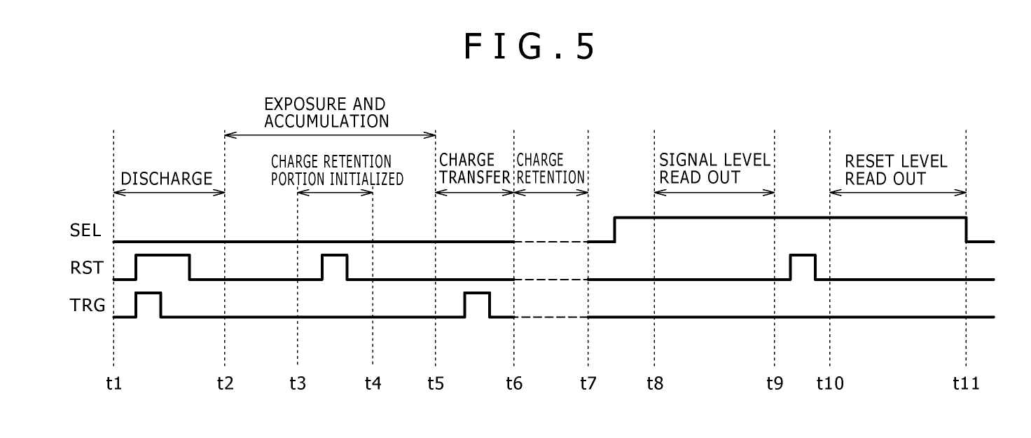

Explained below in reference to the timing chart of FIG. 5 is how the unit pixel 50 is typically driven.

First, between time t1 and time t2, the drive signals RST and TRG are applied in the form of pulses. This causes the electrical charges accumulated in the photodiode 61 and floating diffusion region 63 to be discharged.

After the charges accumulated in the photodiode 61 are swept out, the charges obtained from the light coming from a new object are accumulated in the photodiode 61 between time t2 and time t5. When the drive signal RST is applied between time t3 and time t4 in the form of a pulse, the charges accumulated in the floating diffusion region 63 acting as the charge retention portion are initialized (i.e., reset).

When the drive signal TRG is applied between time t5 and time t6 in the form of a pulse, the charges accumulated in the photodiode 61 are transferred to the floating diffusion region 63 via the transfer gate 62. Thereafter comes the charge retention period between time t6 and time t7.

When the drive signal SEL is driven from Low to High between time t7 and time t8, the voltage reflecting the charges accumulated in the floating diffusion region 63 is read out as the signal level until the drive signal RST is driven High between time t9 and time t10.

When the drive signal RST is driven High between time t9 and time t10, the charges accumulated in the floating diffusion region 63 are reset (discharged) by the reset transistor 64. The reset state lasts until the drive signal SEL is driven Low at time tn. During the reset state, the voltage representing the reset level is read out. This is how a CDS process is performed to remove noise by taking out the difference between the reset level thus read out and the signal level, whereby a noise-free pixel signal is read out.

### EXAMPLE OF DRIVING THE SOLID-STATE IMAGING ELEMENT

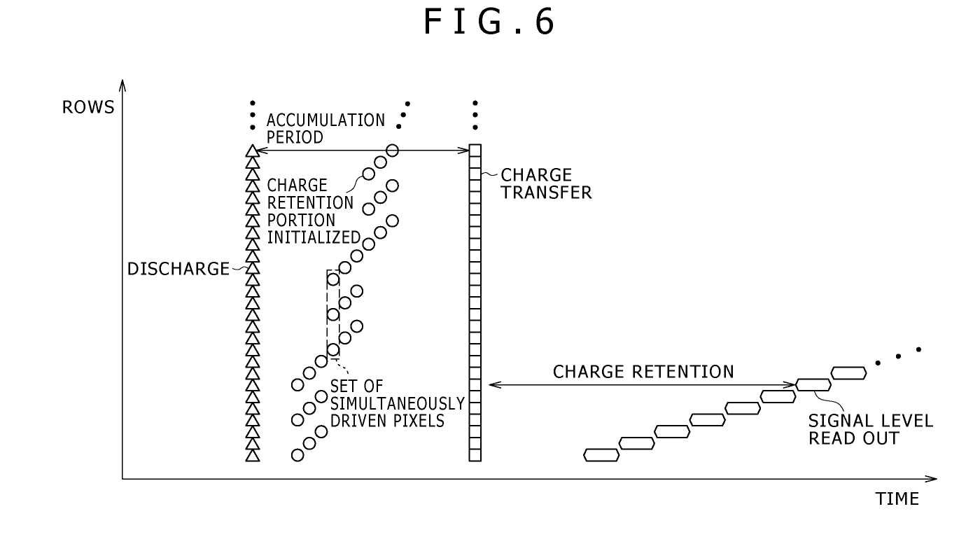

Explained below in reference to FIG. 6 is how the unit pixels 50 are typically driven in increments of rows in the CMOS image sensor 30.

In FIG. 6, the horizontal axis denotes time and the vertical axis represents the rows of unit pixels 50 arrayed two-dimensionally in the CMOS image sensor 30. The discharge, initialization of the charge retention portion, charge transfer, and signal level read-out in the unit pixel 50, all explained above in reference to FIG. 5, are carried out in increments of rows. In FIG. 6, the discharge of the unit pixels 50 is indicated by triangles, the initialization of the charge retention portion by circles, the charge transfer by rectangles, and the signal level read-out by horizontally elongated hexagons.

As shown in FIG. 6, the discharge and the charge transfer are carried out simultaneously on all rows. The signal level is read out on a row-by-row basis. That is, FIG. 6 shows an example in which the CMOS image sensor 30 is driven to perform the global shutter operation involving the simultaneous discharge and charge transfer of all pixels.

As explained above in reference to FIG. 5, the floating diffusion region 63 is initialized after the discharge and prior to the charge transfer. As shown in FIG. 6, the floating diffusion region 63 is initialized in increments of a plurality of rows not adjacent to one another, more specifically in increments of a set of three rows at intervals of two rows.

When the above actions are carried out, the floating diffusion region 63 serving as the charge retention portion is initialized not simultaneously on all pixels but in increments of a plurality of rows not adjacent to one another in the CMOS image sensor carrying out the global shutter operation. This makes it possible to prevent a voltage drop in the power for the reset transistors and to suppress cross talk between the adjacent reset signal lines on the one hand and the charge retention portion on the other hand, the inhibited phenomena being potential disadvantages attributable to the simultaneous initialization of the charge retention portion on all pixels. Because the load resulting from driving all pixels simultaneously in the reset operation is alleviated, it is possible to synchronize the transition timing of the reset operation with the reset operation at signal read time. This in turn leads to minimizing the difference between the pre-transfer reset voltage and the post-read reset voltage, thereby inhibiting the generation of offset noise and enhancing the quality of images taken.

When the floating diffusion region 63 is initialized in increments of a plurality of rows not adjacent to one another, the time required to initialize the charge retention portion on all rows is made shorter than if the initialization is carried out serially row by row. This makes it possible to prevent a decrease in frame rate and improve the quality of images taken.

In the above-described global shutter operation, the discharge and the charge transfer are carried out simultaneously on all rows. That means the drive circuits feeding the drive signals TRG and RST to the transfer gate 62 and to the reset transistor 64 respectively are subject to greater load than during the rolling shutter operation. The increased load has caused a voltage drop in the power for feeding the drive signals TRG and RST to the transfer gate 62 and to the reset transistor 64 respectively, and has led to increased delays in the transition timings of the discharge and charge transfer. That has made it necessary to extend the pulse width of each drive signal, which has entailed hindering the shortening of the period from the discharge to the charge transfer (i.e., exposure and accumulation period).

What follows is an explanation of how the CMOS image sensor is typically driven in a manner that shortens the exposure and accumulation period.

### ANOTHER EXAMPLE OF DRIVING THE SOLID-STATE IMAGING ELEMENT

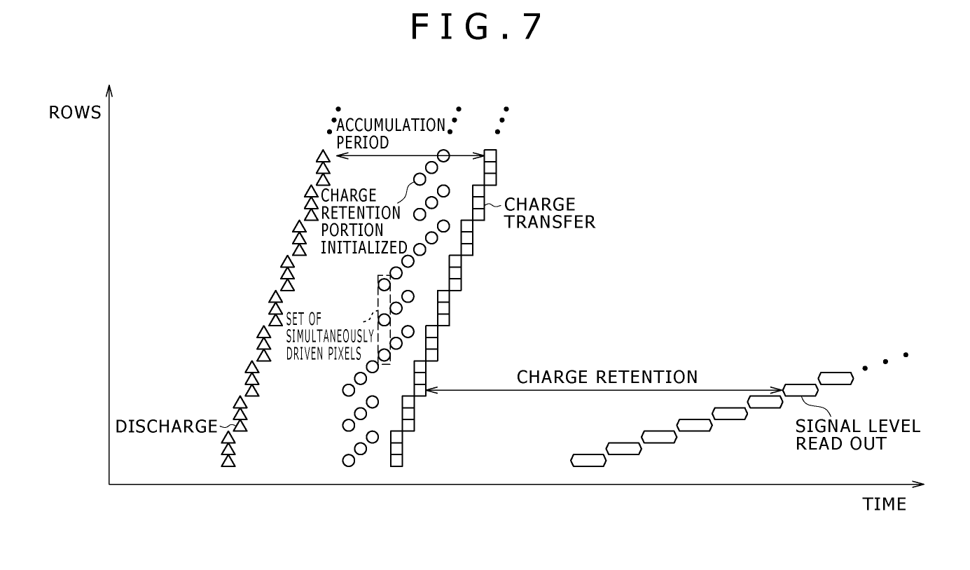

FIG. 7 is an explanatory view of another example in which the unit pixels 50 of the CMOS image sensor 30 are driven in increments of rows.

The drive example shown in FIG. 7 is different from that in FIG. 6 in that the discharge and the charge transfer are performed in increments of a plurality of rows adjacent to one another, more particularly in increments of a set of three adjacent rows.

Also in FIG. 7, as in the drive example of FIG. 6, the floating diffusion region 63 is initialized after the discharge and prior to the charge transfer in increments of a plurality of rows not adjacent to one another, more particularly in increments of a set of three rows at intervals of two rows.

When the above actions are carried out, the floating diffusion region 63 serving as the charge retention portion is initialized not simultaneously on all pixels but in increments of a plurality of rows not adjacent to one another. This makes it possible, as explained above, to suppress the generation of offset noise and enhance the quality of images taken.

Furthermore, because the discharge and the charge transfer are carried out not simultaneously on all pixels but in increments of a plurality of rows adjacent to one another, the drive circuits feeding the drive signals TRG and RST to the transfer gate 62 and to the reset transistor 64 respectively are subject to less load than during the global shutter operation. The reduced load can prevent a voltage drop in the power for feeding the drive signals TRG and RST while minimizing delays in the transition timings of the discharge and charge transfer. This makes it possible to shorten the pulse width of each drive signal, which can shorten the exposure and accumulation period.

Because the discharge and the charge transfer are carried out in increments of a plurality of rows adjacent to one another, the discrepancy of the exposure and accumulation period between rows can be made smaller than when the discharge and the charge transfer are performed in the rolling shutter operation. This in turn minimizes distortions in the images taken.

If the discharge and the charge transfer are carried out in increments of a plurality of rows not adjacent to one another as upon initialization of the charge retention portion, the discrepancy of the exposure and accumulation period can develop at intervals of several rows. This can lead to a distinct distortion of the images taken of a moving object in the high frequency range. For this reason, the discharge and the charge transfer are performed serially in increments of a plurality of rows adjacent to one another.

In the examples of FIGS. 6 and 7, the charge retention portion is initialized simultaneously in increments of three rows, and the discharge and the charge transfer are carried out simultaneously also in increments of three rows. Alternatively, the actions involved may be carried out in increments of a different number of rows. As another alternative, the actions may each be carried out in increments of a different number of rows.

The structure of each of the unit pixels making up the image sensor performing the above-described operations can be made different from the structure shown in FIG. 4. What follows is an explanation of some other unit pixel structures to which the present disclosure can be applied. In the drawings to be cited below and in FIG. 4, like reference numerals designate like or corresponding parts, and their descriptions may be omitted where redundant.

### ANOTHER TYPICAL CIRCUIT STRUCTURE OF THE UNIT PIXEL

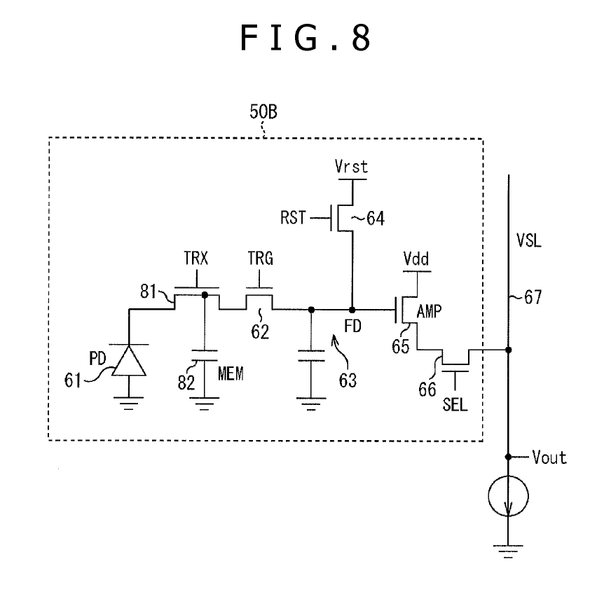

FIG. 8 is a schematic view showing another typical circuit structure of the unit pixel 50.

In addition to the structure of FIG. 4, the unit pixel 50B in FIG. 8 has a transfer gate 81 and a memory portion (MEM) 82 interposed between the photodiode 61 and the transfer gate 62.

When a drive signal TRX is applied to the gate electrode of the transfer gate 81, the charges generated from photoelectric conversion by the photodiode 61 and accumulated therein are transferred via the transfer gate 81. The memory portion 82 accumulates the charges transferred from the photodiode 61 via the transfer gate 81.

Also, when the drive signal TRG is applied to the gate electrode of the transfer gate 62, the charges accumulated in the memory portion 82 are transferred to the floating diffusion region 63 through the transfer gate 62.

That is, in the unit pixel 50B of FIG. 8, the floating diffusion region 63 and memory portion 82 function as the charge retention portion. This charge retention portion is initialized when the drive signals RST and TRG are applied in the form of pulses.

### FURTHER TYPICAL CIRCUIT STRUCTURE OF THE UNIT PIXEL

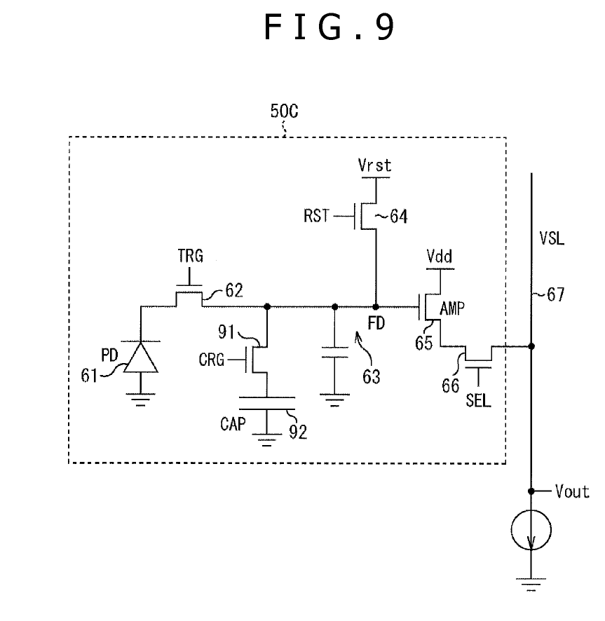

FIG. 9 is a schematic view showing a further typical circuit structure of the unit pixel 50.

In addition to the structure of FIG. 4, the unit pixel 50C in FIG. 9 has a transfer gate 91 and a capacitance element (CAP) 92 interposed between the transfer gate 62 and the floating diffusion region 63.

When a drive signal CRG is applied to the gate electrode of the transfer gate 91, the charges transferred from the photodiode 61 via the transfer gate 62 are forwarded through the transfer gate 91 to the capacitance element 92. The capacitance element 92 accumulates the charges transferred from the photodiode 61 via the transfer gate 62 and forwarded through the transfer gate 91.

When the drive signal TRG is applied to the gate electrode of the transfer gate 62, the transfer gate 62 transfers the charges accumulated in the photodiode 61 to the floating diffusion region 63 and also to the capacitance element 92 via the transfer gate 91.

That is, in the unit pixel 50C of FIG. 9, either or both of the floating diffusion region 63 and capacitance element 92 function as the charge retention portion. If solely the floating diffusion region 63 serves as the charge retention portion, that charge retention portion is initialized when the drive signal RST is applied in the form of a pulse. If the capacitance element 92 alone acts as the charge retention portion, or if both the floating diffusion region 63 and the capacitance element 92 function as the charge retention portion, then the charge retention portion is initialized when the drive signals RST and CRG are both applied in pulses.

### EVEN FURTHER TYPICAL CIRCUIT STRUCTURE OF THE UNIT PIXEL

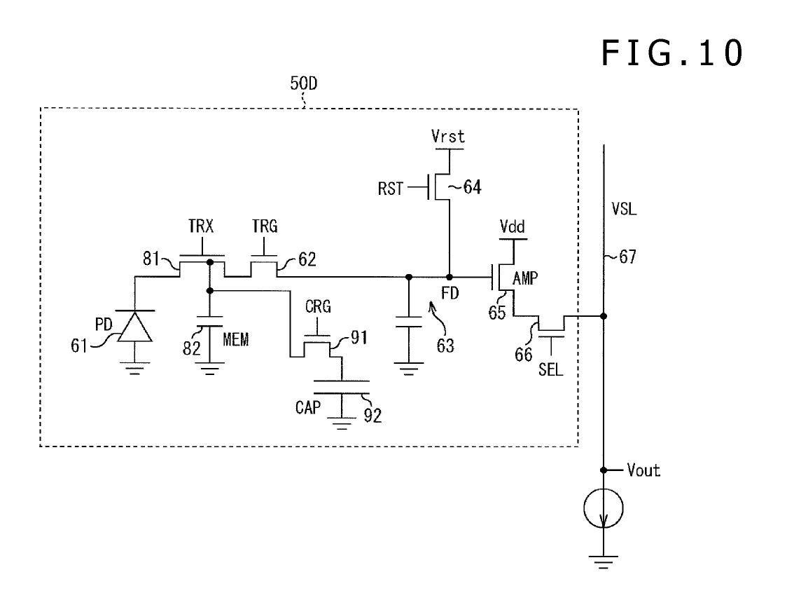

FIG. 10 is a schematic view showing an even further typical circuit structure of the unit pixel 50.

In addition to the structure of FIG. 4, the unit pixel 50D in FIG. 10 has a transfer gate 81 and a memory portion (MEM) 82 interposed between the photodiode 61 and the transfer gate 62 and also has a transfer gate 91 and a capacitance element (CAP) 92 interposed between the transfer gate 62 and the floating diffusion region 63.

It may be appreciated that the transfer gate 81 and memory portion 82 in FIG. 10 are the same as the transfer gate 81 and memory portion 82 in FIG. 8 and that the transfer gate 91 and capacitance element 92 in FIG. 10 are the same as the transfer gate 91 and capacitance element 92 in FIG. 9. Thus these component parts will not be discussed further.

It should be noted that when the drive signal CRG is applied to the gate electrode of the transfer gate 91, the charges transferred from the photodiode 61 via the transfer gate 81 are forwarded through the transfer gate 91 to the capacitance element 92. The capacitance element 92 accumulates the charges transferred from the photodiode 61 via the transfer gate 81 and forwarded through the transfer gate 91.

That is, in the unit pixel 50D of FIG. 10, the floating diffusion region 63 is combined with either or both of the memory portion 82 and capacitance element 92 to function as the charge retention portion. Where the floating diffusion region 63 and memory portion 82 act as the charge retention portion, applying the drive signals RST and TRG in pulses initializes this charge retention portion. Where the floating region 63 and capacitance element 92 serve as the charge retention portion, or where the floating region 63, memory portion 82, and capacitance element 92 function as the charge retention portion, applying the drive signals RST, TRG and CRG in pulses initializes this charge retention portion.

In the foregoing description of the unit pixels, the charge retention portion was shown initialized after the discharge and prior to the charge transfer. Alternatively, the charge retention portion can be initialized before the discharge if a discharge section is provided anew to discharge the electrical charges accumulated in the photodiode 61.

### STILL FURTHER TYPICAL CIRCUIT STRUCTURE OF THE UNIT PIXEL

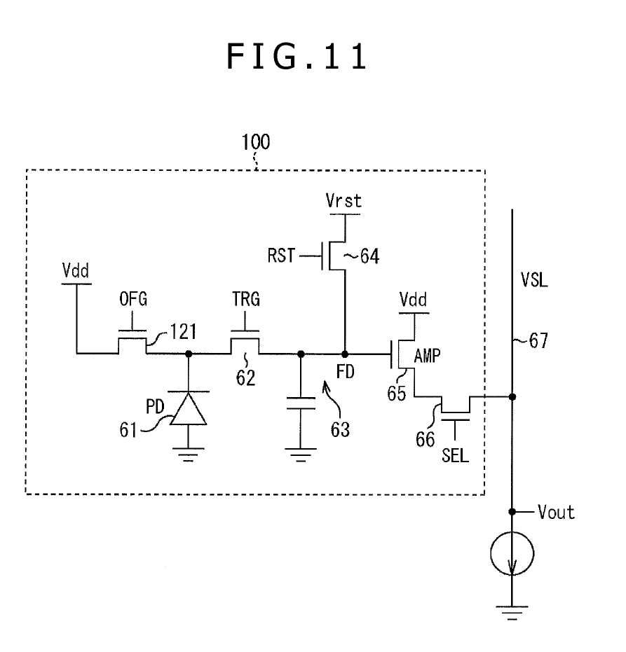

FIG. 11 is a schematic view showing a still further typical circuit structure of the unit pixel arranged to initialize its charge retention portion before the discharge.

Of the component parts in FIG. 11, those with their structural counterparts also found in FIG. 4 are designated by like reference numerals, and their descriptions may be omitted where redundant.

Compared with the unit pixel 50 shown in FIG. 4, the unit pixel 100 in FIG. 11 is supplemented by an overflow gate 121 typically composed of a transistor. In FIG. 11, the overflow gate 121 is connected interposingly between the power source Vdd and the photodiode 61. When supplied with a drive signal OFG from the vertical drive portion 42 via the pixel drive line 46, the overflow gate 121 resets the photodiode 61. That is, the overflow gate 121 discharges the electrical charges accumulated in the photodiode 61.

In this manner, the unit pixel 100 is driven in accordance with the drive signals TRG, RST, SEL and OFG fed from the vertical drive portion 42.

### EXAMPLE OF THE DRIVING THE UNIT PIXEL

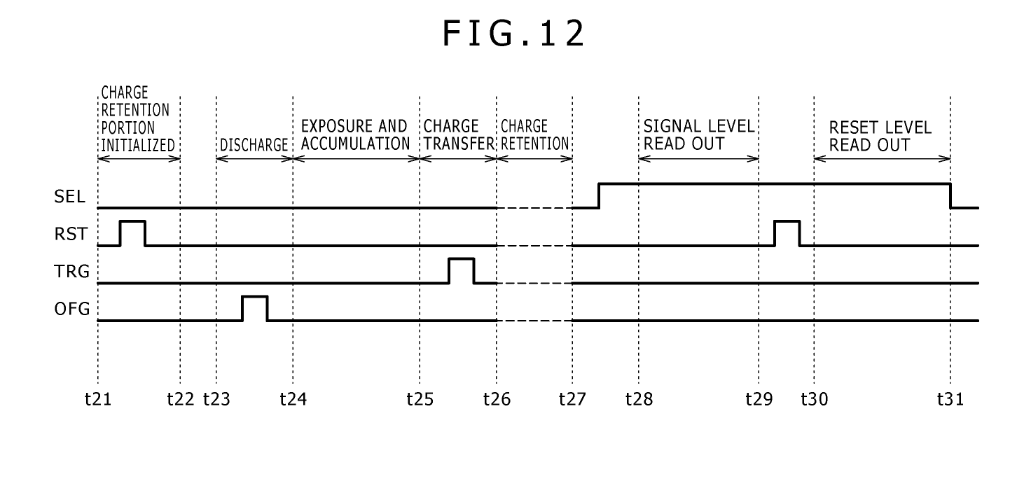

How the unit pixel 100 is typically driven is explained below in reference to the timing chart of FIG. 12.

First, between time t21 and time t22, the drive signal RST is applied in the form of a pulse. This causes the electrical charges accumulated in the floating diffusion region 63 to be discharged (i.e., reset).

Then between time t23 and time 24, the drive signal OFG is applied in the form of a pulse. This causes the electrical charges accumulated in the photodiode 61 to be discharged.

After the charges accumulated in the photodiode 61 are swept out, the charges obtained from the light coming from a new object are accumulated in the photodiode 61 between time t24 and time t25.

The actions performed between time t25 and time t31 are the same as those carried out between time t5 and time t11 in FIG. 5, and thus they will not be discussed further.

As explained above, the overflow gate 121 may be provided in the unit pixel 100 to discharge the electrical charges in the photodiode 61. This arrangement allows the charge retention portion to be initialized prior to the discharge.

### EXAMPLE OF DRIVING THE SOLID-STATE IMAGING ELEMENT

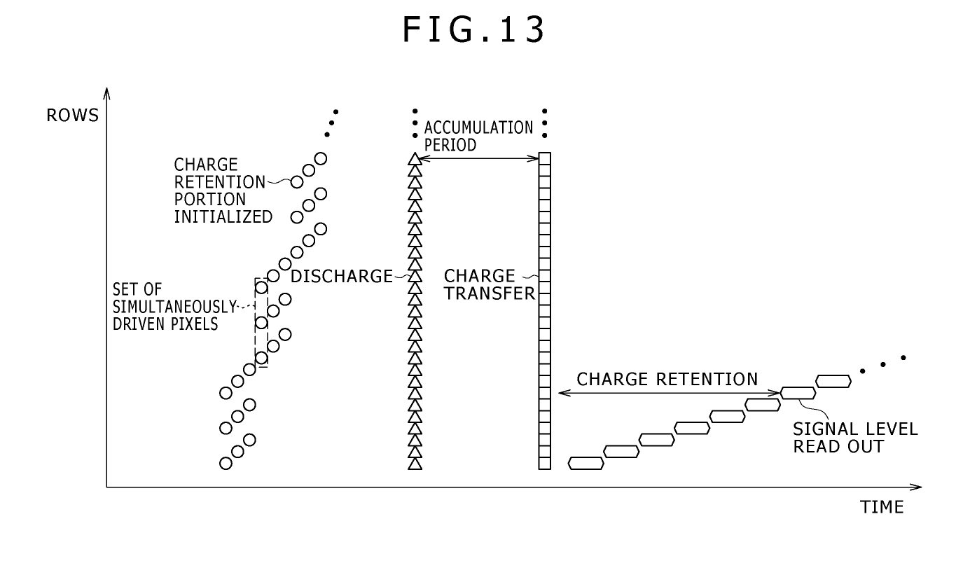

Explained below in reference to FIG. 13 is how the unit pixels 100 in the CMOS image sensor are typically drive in increments of rows.

In FIG. 13, as in FIGS. 6 and 7, the horizontal axis denotes time and the vertical axis represents the rows of unit pixels 100 arrayed two-dimensionally in the CMOS image sensor 30. The initialization of the charge retention portion, discharge, charge transfer, and signal level read-out in the unit pixel 100, all explained above in reference to FIG. 12, are carried out in increments of rows. In FIG. 13, the initialization of the charge retention portion is indicated by circles, the discharge by triangles, the charge transfer by rectangles, and signal level read-out by horizontally elongated hexagons.

As shown in FIG. 13, the discharge and the charge transfer are carried out simultaneously on all rows. The signal level is read out on a row-by-row basis. That is, FIG. 13 shows an example in which the CMOS image sensor 30 is driven to perform the global shutter operation involving the simultaneous discharge and charge transfer of all pixels.

As explained above in reference to FIG. 12, the floating diffusion region 63 prior to the charge transfer is initialized prior to the discharge. As shown in Fig. 13, the floating diffusion region 63 is initialized in increments of a plurality of rows not adjacent to one another, more specifically in increments of a set of three rows at intervals of two rows.

When the above actions are carried out, the floating diffusion region 63 serving as the charge retention portion is initialized not simultaneously on all pixels but in increments of a plurality of rows not adjacent to one another in the CMOS image sensor carrying out the global shutter operation. This makes it possible to prevent a voltage drop in the power for the reset transistors and to suppress cross talk between the adjacent reset signal lines on the one hand and the charge retention portion on the other hand, the inhibited phenomena being potential disadvantages attributable to the simultaneous initialization of the charge retention portion on all pixels. Because the load resulting from driving all pixels simultaneously in the reset operation is alleviated, it is possible to synchronize the transition timing of the reset operation with the reset operation at signal read time. This in turn leads to minimizing the difference between the pre-transfer reset voltage and the post-read reset voltage, thereby inhibiting the generation of offset noise and enhancing the quality of images taken.

When the floating diffusion region 63 is initialized in increments of a plurality of rows not adjacent to one another, the time required to initialize the charge retention portion on all rows is made shorter than if the initialization is carried out serially row by row. This makes it possible to prevent a decrease in frame rate and improve the quality of images taken.

In the above-described global shutter operation, as in the example of FIG. 6, the discharge and the charge transfer are carried out simultaneously on all rows. That means the drive circuits feeding the drive signals TRG and RST to the transfer gate 62 and to the reset transistor 64 respectively are subject to greater load than during the rolling shutter operation. The increased load has caused a voltage drop in the power for feeding the drive signals TRG and RST to the transfer gate 62 and to the reset transistor 64 respectively, and has led to increased delays in the transition timings of the discharge and charge transfer. That has made it necessary to extend the pulse width of each drive signal, which has entailed hindering the shortening of the period from the discharge to the charge transfer (i.e., exposure and accumulation period).

What follows is an explanation of how the CMOS image sensor is typically driven in a manner that shortens the exposure and accumulation period.

### ANOTHER EXAMPLE OF DRIVING THE SOLID-STATE IMAGING ELEMENT

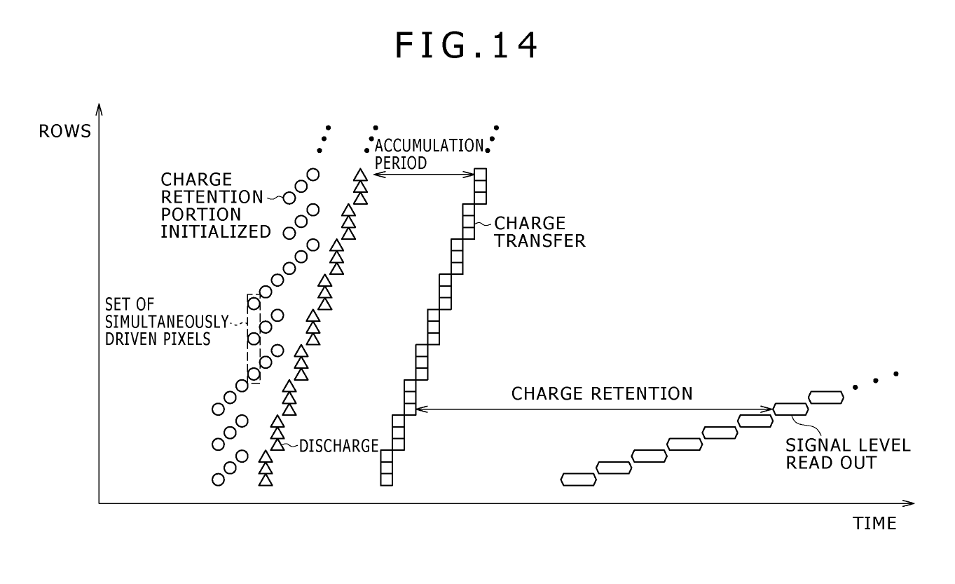

FIG. 14 is an explanatory view of another example in which the unit pixels 100 of the CMOS image sensor 30 are driven in increments of rows.

The drive example shown in FIG. 14 is different from that in FIG. 13 in that the discharge and the charge transfer are performed serially in increments of a plurality of rows adjacent to one another, more particularly in increments of a set of three adjacent rows.

Also in FIG. 14, as in the drive example of FIG. 13, the floating diffusion region 63 prior to the charge transfer is initialized prior to the discharge in increments of a plurality of rows not adjacent to one another, more particularly in increments of a set of three rows at intervals of two rows.

When the above actions are carried out, the floating diffusion region 63 serving as the charge retention portion is initialized not simultaneously on all pixels but in increments of a plurality of rows not adjacent to one another. This makes it possible, as explained above, to suppress the generation of offset noise and enhance the quality of images taken.

Furthermore, because the discharge and the charge transfer are carried out not simultaneously on all pixels but in increments of a plurality of rows adjacent to one another, the drive circuits feeding the drive signals TRG and RST to the transfer gate 62 and to the reset transistor 64 respectively are subject to less load than during the global shutter operation. The reduced load can prevent a voltage drop in the power for feeding the drive signals TRG and RST while minimizing delays in the transition timings of the discharge and charge transfer. This makes it possible to shorten the pulse width of each drive signal, which can shorten the exposure and accumulation period.

Because the discharge and the charge transfer are carried out serially in increments of a plurality of rows adjacent to one another, the discrepancy of the exposure and accumulation period between rows can be made smaller than when the discharge and the charge transfer are performed in the rolling shutter operation. This in turn minimizes distortions in the images taken.

In the drive examples of FIGS. 13 and 14, the charge retention portion (floating diffusion region 63) is initialized serially in increments of a set of three rows at intervals of two rows. Alternatively, the initialization may be carried out in increments of a different number of rows at intervals of a desired number of rows.

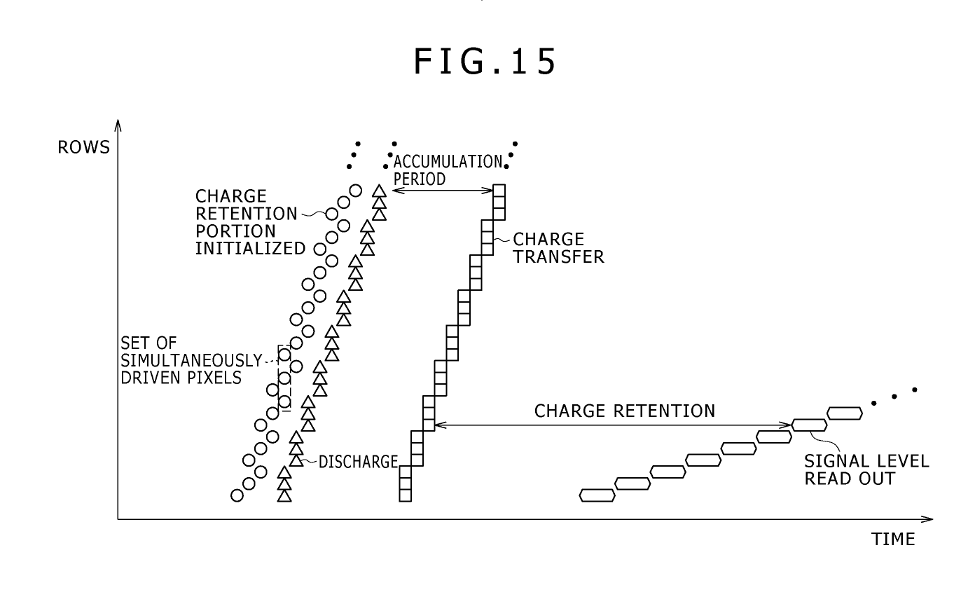

For example, as shown in FIG. 15, the charge retention portion may be initialized serially in increments of a set of three rows at intervals of one row. When the number of rows at intervals of which the rows are initialized is made smaller this way and when the discharge and the charge transfer are performed serially at intervals of a plurality of rows adjacent to one another, it is possible to shorten the period from the time the charge retention portion is initialized to the time the discharge (or charge transfer) is carried out. This can reduce the accumulation of dark current in the charge retention portion.

However, if the number of rows at intervals of which the charge retention portion is initialized is made too small, cross talk between the adjacent reset signal lines on the one hand and the charge retention portion on the other hand can generate offset noise. Thus an optimal number of rows at intervals of which the pixels are to be driven should preferably be set through a trade-off between the period from initialization of the charge retention portion until the discharge (or charge transfer) on the one hand, and cross talk between the adjacent reset signal lines and the charge retention portion on the other hand of driven rows.

Explained above in reference to FIG. 15 was the drive example in which the charge retention portion is initialized prior to the discharge in increments of rows at intervals of a reduced number of rows. Obviously, as discussed above in reference to FIGS. 6 and 7, the charge retention portion may be initialized after the discharge and prior to the charge transfer also in increments of rows at intervals of a reduced number of rows.

The structure of each of the unit pixels making up the image sensor performing the above-described operations can be made different from the structure shown in FIG. 11. Explained below are some other unit pixel structures to which the present disclosure can be applied. In the drawings to be cited below and in FIG. 11, like reference numerals designate like or corresponding parts, and their descriptions may be omitted where redundant.

### ANOTHER TYPICAL CIRCUIT STRUCTURE OF THE UNIT PIXEL

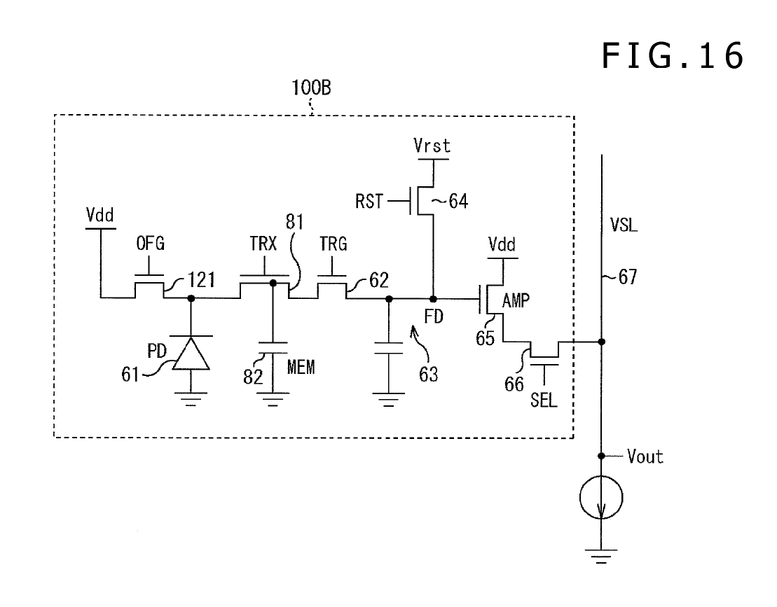

FIG. 16 is a schematic view showing yet another typical circuit structure of the unit pixel 100.

In addition to the structure of FIG. 11, the unit pixel 100B in FIG. 16 has a transfer gate 81 and a memory portion (MEM) 82 interposed between the photodiode 61 and the transfer gate 62. It may be appreciated that the transfer gate 81 and memory portion 82 in FIG. 16 are the same as the transfer gate 81 and memory portion 82 in FIG. 8. Thus these component parts will not be discussed further.

That is, in the unit pixel 100B of FIG. 16, the floating diffusion region 63 and memory portion 82 function as the charge retention portion. This charge retention portion is initialized when the drive signals RST and TRG are applied in pulses.

### FURTHER TYPICAL CIRCUIT STRUCTURE OF THE UNIT PIXEL

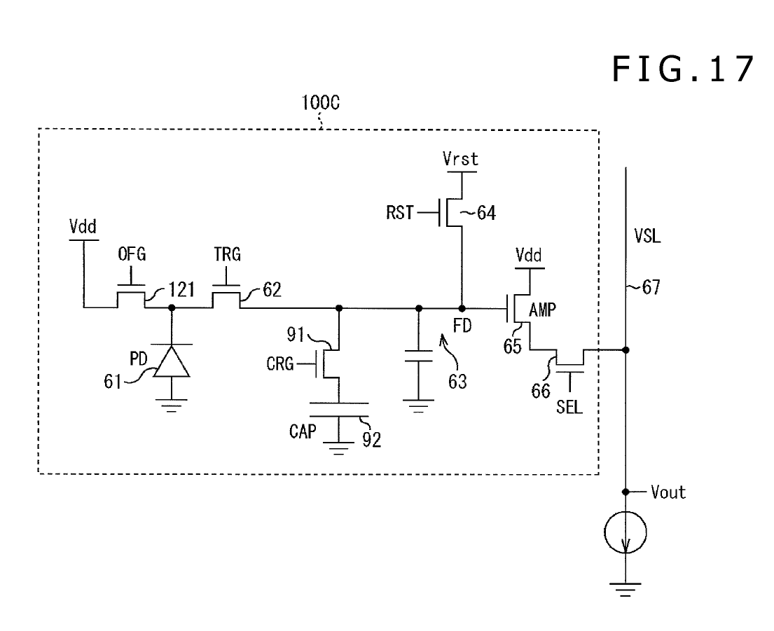

FIG. 17 is a schematic view showing another typical circuit structure of the unit pixel 100.

In addition to the structure of FIG. 11, the unit pixel 100C in FIG. 17 has a transfer gate 91 and a capacitance element (CAP) 92 interposed between the transfer gate 62 and the floating diffusion region 63. It may be appreciated that the transfer gate 91 and capacitance element 92 in FIG. 17 are the same as the transfer gate 91 and capacitance element 92 in FIG. 9. Thus these component parts will not be discussed further.

That is, in the unit pixel 100C of FIG. 16, either or both of the floating diffusion region 63 and capacitance element 92 function as the charge retention portion. If solely the floating diffusion region 63 serves as the charge retention portion, that charge retention portion is initialized when the drive signal RST is applied in the form of a pulse. If the capacitance element 92 alone acts as the charge retention portion, or if both the floating diffusion region 63 and the capacitance element 92 function as the charge retention portion, then the charge retention portion is initialized when the drive signals RST and CRG are both applied in pulses.

### EVEN FURTHER TYPICAL CIRCUIT STRUCTURE OF THE UNIT PIXEL

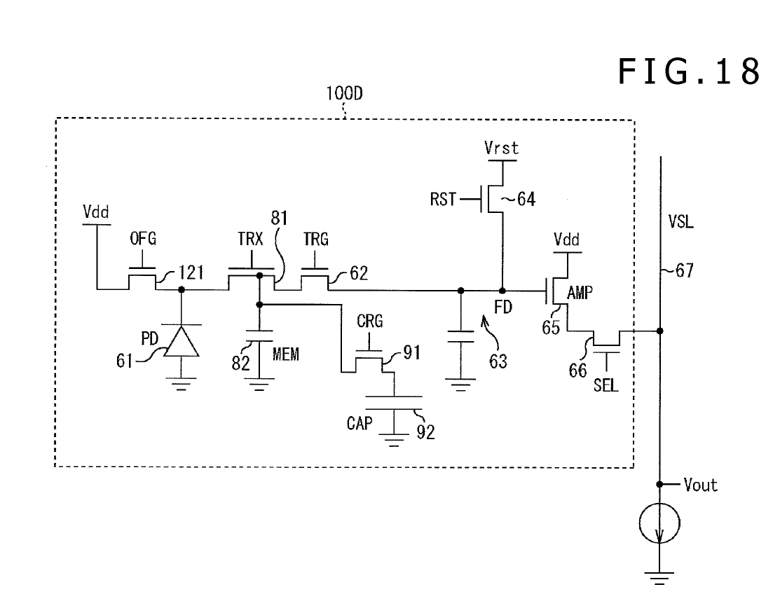

FIG. 18 is a schematic view showing a further typical circuit structure of the unit pixel 100.

In addition to the structure of FIG. 11, the unit pixel 100D in FIG. 18 has a transfer gate 81 and a memory portion 82 interposed between the photodiode 61 and the transfer gate 62 and also has a transfer gate 91 and a capacitance element 92 interposed between the transfer gate 62 and the floating diffusion region 63. It may be appreciated that the transfer gate 81 and memory portion 82 in FIG. 18 are the same as the transfer gate 81 and memory portion 82 in FIG. 10 and that the transfer gate 91 and capacitance element 92 in FIG. 18 are also the same as the transfer gate 91 and capacitance element 92 in FIG. 10. Thus these component parts will not be discussed further.

That is, in the unit pixel 100D of FIG. 18, the floating diffusion region 63 is combined with either or both of the memory portion 82 and capacitance element 92 to function as the charge retention portion. Where the floating diffusion region 63 and memory portion 82 act as the charge retention portion, applying the drive signals RST and TRG in pulses initializes this charge retention portion. Where the floating region 63 and capacitance element 92 serve as the charge retention portion, or where the floating region 63, memory portion 82, and capacitance element 92 function as the charge retention portion, applying the drive signals RST, TRG and CRG in pulses initializes this charge retention portion.

In the foregoing description of the unit pixel, the overflow gate 121 was shown provided to initialize the charge retention portion prior to the discharge as explained in reference to FIGS. 12 through 14. Alternatively, with the overflow gate 121 disabled, the charge retention portion may be initialized after the discharge and prior to the charge transfer as discussed above in reference to FIGS. 5 through 7.

### TYPICAL STRUCTURE OF THE ELECTRONIC APPARATUS EMBODYING THE PRESENT DISCLOSURE

The present disclosure is not limited to being embodied as the solid-state imaging element. Alternatively, this disclosure may be embodied as any one of diverse electronic apparatuses that utilize the solid-state imaging element in their imaging portion (photoelectric conversion portion), such as imaging apparatuses including digital still cameras and video cameras, portable terminal devices furnished with the imaging function, and copiers that use the solid-state imaging element in their image reader. The solid-state imaging element may be formed as a one-chip element or as a module which possesses the imaging function and which integrates the imaging portion and the signal processing portion or optical system into a package.

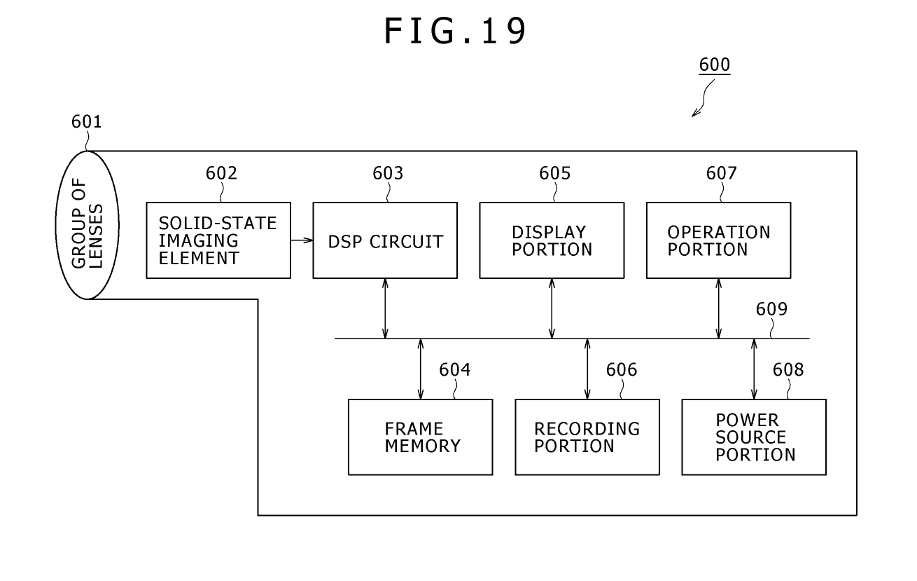

FIG. 19 is a block diagram showing a typical structure of an imaging apparatus 600 as an electronic apparatus embodying the present disclosure.

The imaging apparatus 600 in FIG. 19 includes an optical portion 601 typically composed of a group of lenses, a solid-state imaging element (imaging device) 602 adopting any of the above-described structures of the unit pixels 50, and a DSP circuit 603 serving as a camera signal processing circuit. The imaging apparatus 600 also includes a frame memory 604, a display portion 605, a recording portion 606, an operation portion 607, and a power source portion 608. The DSP circuit 603, frame memory 604, display portion 605, recording portion 606, operation portion 607, and power source portion 608 are interconnected via a bus line 609.

The optical portion 601 takes incident light (image light) from an object to form an image on the imaging area of the solid-state imaging element 602. The solid-state imaging element 602 converts the amount of the incident light imaged on the imaging area by the optical portion 601 into an electrical signal per pixel and outputs the signal as a pixel signal. The solid-state imaging element 602 in this setup may be implemented using a solid-state imaging element such as the CMOS image sensor 30 of which the structures have been discussed above, i.e., the solid-state imaging element allowing distortion-free images to be taken upon global exposure.

For example, the display portion 605 may be composed of a panel-type display device such as a liquid crystal display panel or an organic electroluminescence panel, displaying moving or still images taken by the solid-state imaging element 602. The recording portion 606 records the moving or still images taken by the solid-state imaging element 602 to suitable recording media such as video tapes or DVD's (Digital Versatile Disks).

Operated by the user, the operation portion 607 issues operation commands to enable diverse functions provided by the imaging apparatus 600. The power source portion 608 serves as power sources that power the DSP circuit 603, frame memory 604, display portion 605, recording portion 606, and operation portion 607 as needed.

As described above, the CMOS image sensor 30 embodying the present disclosure and used as the solid-state imaging element 602 allows its charge retention portion to be initialized in increments of a plurality of rows not adjacent to one another. This structure can minimize the difference between the pre-transfer reset voltage and the post-read reset voltage and inhibit the generation of offset noise. That in turn enhances the quality of images taken by the imaging apparatus 600 such as the camera module for mobile devices including video cameras, digital still cameras, and mobile phones.

In the foregoing description, the present disclosure was shown embodied as the CMOS image sensor having the unit pixels arrayed in rows and columns, each of the unit pixels detecting a signal charge level reflecting the amount of visible light as a physical quantity. However, the embodiment as the CMOS sensor is not limitative of the present disclosure. This disclosure may also be embodied as any column type solid-state imaging element having a column processing portion allotted to each of the pixel columns making up its pixel array portion.

The present disclosure is not limited to being embodied as the solid-state imaging element that detects the distribution of the amount of the incident visible light and turns the detected light distribution into images. Alternatively, the present disclosure may be embodied as a solid-state imaging element that detects the distribution of the amount of incident infrared rays, X-rays, or particles and turns the detected distribution into images. This disclosure may also be embodied as any one of solid-state imaging elements each acting as a physical quantity distribution detection instrument in a broader sense, such as a fingerprint sensor that detects the distribution of other physical quantities including pressure and electrostatic capacitance levels and turn the detected distribution into images.

It should be understood by those skilled in the art that various modifications, combinations, sub-combinations and alterations may occur depending on design requirements and other factors in so far as they are within the scope of the appended claims or the equivalents thereof.

The present disclosure contains subject matter related to that disclosed in Japanese Priority Patent Application JP 2010-279509 filed in the Japan Patent Office on Dec. 15, 2010, the entire content of which is hereby incorporated by reference.

What is claimed is:

1. A solid-state imaging element comprising:
a pixel array portion configured to have a plurality of unit pixels arrayed two-dimensionally, said unit pixels being furnished with a photoelectric conversion portion, a transfer section, and a reset section, said transfer section being configured to transfer electrical charges accumulated in said photoelectric conversion portion to a charge retention portion, said reset section being configured to reset the electrical charges of said charge retention portion; and
a drive control section configured to control the driving of said unit pixels;
wherein said drive control section controls the driving of said unit pixels in such a manner that prior to the charge transfer by said transfer section, said reset section resets the electrical charges of said charge retention portion in increments of a plurality of rows of said unit pixels, said plurality of rows being not adjacent to one another.

2. The solid-state imaging element according to claim 1, wherein said drive control section controls the driving of said unit pixels in such a manner that said transfer section performs the charge transfer simultaneously on all unit pixels in said pixel array portion.

3. The solid-state imaging element according to claim 1, wherein said drive control section controls the driving of said unit pixels in such a manner that said photoelectric conversion portion is discharged simultaneously for all unit pixels in said pixel array portion.

4. The solid-state imaging element according to claim 1, wherein said drive control section controls the driving of said unit pixels in such a manner that said photoelectric conversion portion is discharged and the charge transfer is performed by the transfer section in increments of a plurality of rows of said unit pixels in said pixel array portion, said plurality of rows being adjacent to one another.

5. The solid-state imaging element according to claim 1, wherein said reset section discharges the electrical charges accumulated in said photoelectric conversion portion; and
said drive control section controls the driving of said unit pixels in such a manner that after the discharging of said photoelectric conversion portion by said reset section and prior to the charge transfer by said transfer section, said reset section resets the electrical charges of said charge retention portion in increments of a plurality of rows of said unit pixels in said pixel array portion, said plurality of rows being not adjacent to one another.

6. The solid-state imaging element according to claim 1, further comprising:
a discharge section configured to discharge the electrical charges accumulated in said photoelectric conversion portion.

7. The solid-state imaging element according to claim 6, wherein said drive control section controls the driving of said unit pixels in such a manner that prior to the discharging of said photoelectric conversion portion by said discharge section, said reset section resets the electrical charges of said charge retention portion in increments of a plurality of rows of said unit pixels in said pixel array portion, said plurality of rows being not adjacent to one another.

8. The solid-state imaging element according to claim 1, wherein said drive control section controls the driving of said unit pixels in such a manner that said reset section resets the electrical charges of said charge retention portion in increments of n rows at intervals of m rows of said unit pixels in said pixel array portion.

9. The solid-state imaging element according to claim 8, wherein m is 1.

10. The solid-state imaging element according to claim 1, wherein said charge retention portion is a floating diffusion region.

11. The solid-state imaging element according to claim 10, wherein said charge retention portion is a capacitance element furnished apart from said floating diffusion region.

12. The solid-state imaging element according to claim 1, further comprising:
a read section configured to read a voltage reflecting the electrical charges of said charge retention portion;
wherein said drive control section controls the driving of said unit pixels in such a manner that
the reading by said read section of the voltage as a signal level reflecting the electrical charges accumulated in said charge retention portion after the charge transfer,
the resetting by said reset section of the electrical charges accumulated in said charge retention portion after the charge transfer, and
the reading by said read section of the voltage as a reset level reflecting the electrical charges of said charge retention portion after the charge reset
are carried out serially in increments of a row of said unit pixels.

13. The solid-state imaging element according to claim 12, further comprising:
a calculation section configured to calculate a difference between said signal level and said reset level read out by said read section.

14. A driving method for use with a solid-state imaging element including
a pixel array portion configured to have
a plurality of unit pixels arrayed two-dimensionally, said unit pixels being furnished with a photoelectric conversion portion, a transfer section, and a reset section, said transfer section being configured to transfer electrical charges accumulated in said photoelectric conversion portion to a charge retention portion, said reset section being configured to reset the electrical charges of said charge retention portion; and
a drive control section configured to control the driving of said unit pixels;
said driving method comprising:
causing said drive control section to control the driving of said unit pixels in such a manner that prior to the charge transfer by said transfer section, said reset section resets the electrical charges of said charge retention portion in increments of a plurality of rows of said unit pixels, said plurality of rows being not adjacent to one another.

15. An electronic apparatus comprising:
a solid-state imaging element including
a pixel array portion configured to have a plurality of unit pixels arrayed two-dimensionally, said unit pixels being furnished with a photoelectric conversion portion, a transfer section, and a reset section, said transfer section being configured to transfer electrical charges accumulated in said photoelectric conversion portion to a charge retention portion, said reset section being configured to reset the electrical charges of said charge retention portion; and
a drive control section configured to control the driving of said unit pixels;
wherein said drive control section controls the driving of said unit pixels in such a manner that prior to the charge transfer by said transfer section, said reset section resets the electrical charges of said charge retention portion in increments of a plurality of rows of said unit pixels, said plurality of rows being not adjacent to one another.
